(19) United States
(12) Patent Application Publication
(10) Pub. No.: US 2009/0170311 A1
(43) Pub. Date: Jul. 2, 2009

(54) METHOD FOR FABRICATING CONTACT IN SEMICONDUCTOR DEVICE

(75) Inventors: Choon Hwan Kim, Seongnam-si (KR); Kyoung Bong Routh, Icheon-si (KR); II Cheol Rho, Icheon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/346,669

(22) Filed: Dec. 30, 2008

(30) Foreign Application Priority Data
Jan. 2, 2008 (KR) 10-2008-0000381

(51) Int. Cl. H01L 21/285; H01L 21/44; H01L 21/443

(52) U.S. Cl. 438/655; 438/664; 438/680; 257/E21.165; 257/E21.478; 257/E21.476

(57) ABSTRACT

A method for fabricating a contact in a semiconductor device includes forming an insulating film having a contact hole over a bottom film, forming a thin metal film in the exposed portion of the bottom film by supplying a reaction gas containing a metal component to a surface of the bottom film exposed by the contact hole, forming a metal silicide film by performing an annealing process on the thin metal film, and forming a metal film over the metal silicide film to fill the contact hole.

### CROSS-REFERENCE TO RELATED APPLICATIONS

Priority to Korean patent application number 10-2008-0000381, filed on Jan. 2, 2008, the disclosure of which is incorporated by reference in its entirety, is claimed.

### BACKGROUND OF THE INVENTION

1. Field of the Invention

The present invention relates generally to a method for fabricating a contact in a semiconductor device, and more particularly, to a method for fabricating a contact in a semiconductor device, which can have lower contact resistance.

2. Description of Related Technology

Generally, semiconductor devices include several active devices and passive devices. A transistor is a representative active device and a register is a representative passive device. During integration of several devices on a single substrate, a contact is necessary for electrical connection between devices or electrical connection between one portion of the device and another device. For example, in a DRAM memory device, the gate is arranged over the substrate with diffusion areas, such as source/drain areas. One of the diffusion areas can be connected to the capacitor via a storage contact, And the other of the diffusion areas can be connected to a bit line via a bit line contact.

For a storage contact and a bit line contact, because metal material and a silicon substrate are in contact with each other, an energy barrier phenomenon is formed at an interface between them. Therefore, upon applying voltage, electrons and holes do not move smoothly, and subsequently the contact resistance increases so that the electrical performance of the devices deteriorates.

In integrated devices having a pitch of 60 nm, the contact resistance between the metal and the silicon substrate can be reduced by performing an annealing process after forming a thin titanium (Ti) film using a PVD (Physical Vapor Deposition) method to form a titanium silicide (TiSi₂) film. However, because the size of the contact is considerably reduced for devices having a pitch less than, e.g., 50 nm as higher integration is needed, the thickness of the thin titanium film formed tends to be irregular upon forming the thin titanium film using the PVD method. The contact resistance will be increased due to the irregular thickness of the thin titanium film formed. As the case may be, instead of forming the thin titanium film using a PVD method, a titanium chloride (TiCl₄) film may be formed using PEPVD (Plasma Enhanced PVD) and thereafter the titanium film may be formed on the titanium chloride film using a CVD (Chemical Vapor Deposition) method. In this case, the vaporization temperature for CVD is at least about 600° C., and excessive titanium silicide (TiSi₂) is formed during the process at such temperature conditions, which results in heat-unstable agglomeration. Such heat-unstable agglomeration causes the contact resistance to be increased.

### SUMMARY OF THE INVENTION

Embodiments of the present invention are directed to a method for fabricating a contact in a semiconductor device, which can reduce the contact resistance and thereby enhance electrical performance of the devices.

The method for fabricating a contact in a semiconductor device according to one embodiment of the present invention includes forming an insulating film having contact hole over a bottom film, forming a thin metal film in an exposed portion of the bottom film by supplying a reaction gas containing a metal component to a surface of the bottom film exposed by the contact hole, forming a metal silicide film by performing an annealing process on the thin metal film, and forming a metal film over the metal silicide film to fill the contact hole. The bottom film preferably includes silicon. The reaction gas preferably includes titanium fluoride TiF₄ gas. The supply of the reaction gas is preferably performed to form the thin metal film having a thickness of 1 nm to 5 nm.

The annealing process can be performed using a rapid thermal processing method or a furnace annealing method.

As an example, the method further includes performing a pre-cleaning process for removing a native oxide film, which may form on the exposed surface of the bottom film before forming the thin metal film.

### BRIEF DESCRIPTION OF THE DRAWINGS

For a more complete understanding of the disclosure, reference should be made to the following detailed description and accompanying drawings.

FIGS. 1 to 4 are cross-sectional views showing a method for fabricating a contact in a semiconductor device according to the present invention.

While the disclosed method is susceptible of embodiments in various forms, specific embodiments are illustrated in the drawings (and will hereafter be described), with the understanding that the disclosure is intended to be illustrative, and is not intended to limit the invention to the specific embodiments described and illustrated herein.

### DESCRIPTION OF SPECIFIC EMBODIMENTS

Hereinafter, a method for fabricating a contact in a semiconductor device according to the present invention will be described in detail with reference to the accompanying drawings.

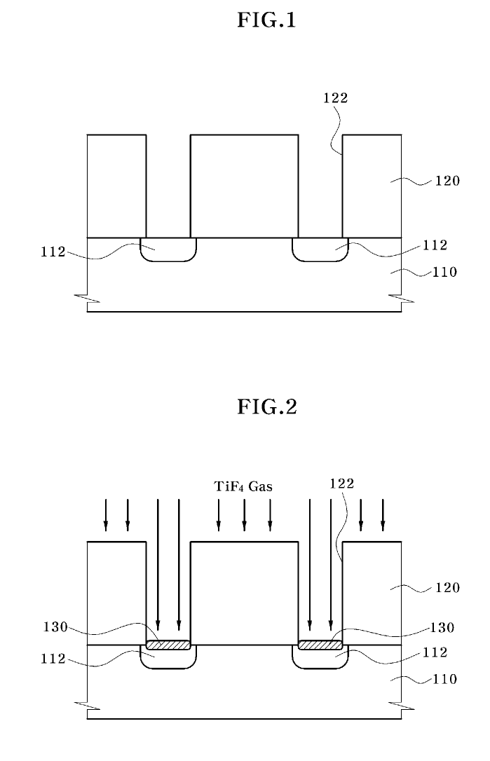

FIGS. 1 to 4 are cross-sectional views showing a method for fabricating a contact in a semiconductor device according to the present invention.

Referring to FIG. 1, an insulating film pattern 120 is formed on a substrate 110, such as silicon substrate. A diffusion area 112, such as source area or drain area, in which impurities are doped, is disposed on a top surface of the substrate 110. The insulating film pattern 120 has a contact hole 122, which is an opening for exposing the diffusion area 112. To form the insulating film pattern 120 having the contact hole 122, an insulating film is formed on the substrate, and then a mask film pattern, such as photoresist film pattern (not shown), is formed over the insulating film. Consequently, the contact hole 122 is formed to expose the diffusion area 112 of the substrate 110 by removing an exposed portion of the insulating film by means of an etch process using the mask film pattern as an etch mask. After forming the contact hole 122, the mask film pattern is removed. A pre-cleaning process can be performed for removing a native oxide film, which may form over the exposed diffusion area 112.

Referring to FIG. 2, after forming the contact hole 122, a reaction gas containing a metal component is injected from a front surface. Titanium fluoride (TiF₄) gas is preferably used as the reaction gas containing the metal component in this embodiment. As the titanium fluoride (TiF₄) gas is injected, a reaction between silicon (Si) of the substrate 110 and the injected titanium fluoride (TiF₄) gas is generated as follows:

TiF₄(g)+Si(s)→Ti(s)+SiF₄(g) [Reaction Equation]

A thin titanium film 130 is formed on the exposed surface of the diffusion area 112 according to the above reaction equation and the remaining components are exhausted in the form of silicon fluoride (SiF₄) gas. Because the thin titanium film 130 is formed using injection of the titanium fluoride (TiF₄) gas, the thin titanium film can be formed at a uniform thickness in a range of, for example, 1 nm to 5 nm.

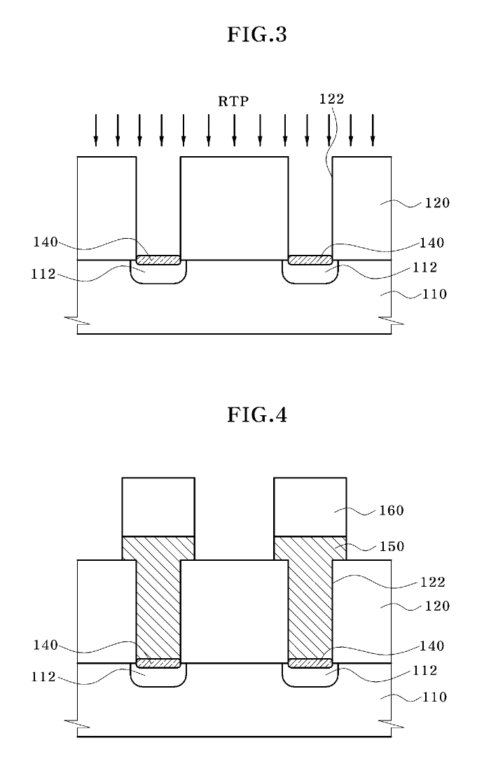

Referring to FIG. 3, a titanium silicide (TiSi₂) film 140 is formed on a surface of the diffusion area 112 by performing an annealing process on a front surface of the resultant structure after the thin titanium film (130 of FIG. 2) is formed. This annealing process is performed using a RTP (Rapid Thermal Processing) method at a temperature range of about 550° C. to 850° C. Alternatively, the annealing process can take place in a furnace. In this case, the temperature range is approximately 550° C. to 850° C. Because the thin titanium film 130 is formed at a uniform thickness through injection of the titanium fluoride (TiF₄) gas as described above referring to FIG. 2, the titanium silicide (TiSi₂) film 140 is also formed at a uniform thickness.

Referring to FIG. 4, a metal film, e.g., a tungsten (W) film, is formed to fill the contact hole 122. Although not shown in the drawing, a barrier metal film can be formed before forming the tungsten film. Then, a hard mask film pattern 160 is formed over the tungsten film. A tungsten contact 150 is formed by exposing a surface of the insulating film pattern 120 by an etch process using the hard mask film pattern 160 as an etch mask. Thereafter, the hard mask film pattern 160 can be removed or left in place, as necessary. As such, the tungsten contact 150 can be used as a bit line contact connecting the diffusion area 112 and a bit line, or as a storage contact connecting the diffusion area 112 and a capacitor.

According to the present invention, it is possible to form a thin titanium film having a uniform thickness by supplying titanium fluoride (TiF₄) gas to form the thin titanium film, and therefore form the regular titanium silicide (TiSi₂) film by a subsequent annealing process, which results in reducing contact resistance between the metal and the silicon.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a contact in semiconductor devices, the method comprising:
forming an insulating film having a contact hole over a bottom film;
forming a thin metal film in an exposed portion of the bottom film by supplying a reaction gas comprising a metal component to a surface of the bottom film exposed by the contact hole;
forming a metal silicide film by performing an annealing process on the thin metal film; and
forming a metal film over the metal silicide film to fill the contact hole.

2. The method of claim 1, comprising forming the bottom film with a material comprising silicon.

3. The method of claim 1, wherein the reaction gas comprises titanium fluoride TiF₄ gas.

4. The method of claim 1, comprising supplying the reaction gas to form the thin metal film to a thickness in a range of 1 nm to 5 nm.

5. The method of claim 1, comprising performing the annealing process using a rapid thermal processing method or a furnace annealing method.

6. The method of claim 1, wherein a native oxide film forms on an exposed surface of the bottom film before forming the thin metal film and further comprising performing a pre-cleaning process for removing the native oxide film.

7. The method of claim 1, wherein the exposed portion of the bottom film comprises a diffusion area.

8. The method of claim 1, further comprising forming a barrier metal film before forming the metal film over the metal silicide film.

9. The method of claim 1, wherein the metal film formed over the metal silicide film comprises a tungsten film.

10. The method of claim 1, further comprising forming a hard mask film pattern over the metal film and etching the metal film using the hard mask film pattern as an etch mask.
